(19) United States
(12) Patent Application Publication
(10) Pub. No.: US 2026/0024764 A1
(43) Pub. Date: Jan. 22, 2026

(54) HIGH-ENTROPY SINGLE CRYSTAL CORE-SHELL STRUCTURED CATHODE ACTIVE MATERIAL FOR LMFP/LFP AND NCMA/NMx

(71) Applicant: GM GLOBAL TECHNOLOGY OPERATIONS LLC, Detroit, MI (US)

(72) Inventors: Jingyuan LIU, Shanghai (CN); Xin ZHANG, Shanghai (CN); Haijing LIU, Shanghai (CN)

(21) Appl. No.: 18/812,695

(22) Filed: Aug. 22, 2024

(30) Foreign Application Priority Data
Jul. 16, 2024 (CN) 2024109539321

(51) Int. Cl. H01M 4/62; C30B 29/14; C30B 29/22; H01M 4/02; H01M 4/131; H01M 4/136; H01M 4/36; H01M 4/525; H01M 4/58; H01M 10/0525

(52) U.S. Cl. CPC H01M 4/62; C30B 29/14; C30B 29/22; H01M 4/131; H01M 4/136; H01M 4/366; H01M 4/525; H01M 4/5825; H01M 10/0525; H01M 2004/028

(57) ABSTRACT

A cathode electrode includes a cathode current collector and a cathode active material layer arranged on at least one side of the cathode current collector. The cathode active material layer includes cathode active material comprising a plurality of cores each including a single crystal particle and a high entropy layer encapsulating each of the single crystal particles of the plurality of cores. The high entropy layer includes at least 5 different transition metal elements.

### CROSS-REFERENCE TO RELATED APPLICATIONS

This application claims the benefit of Chinese Patent Application No. 202410953932.1, filed on Jul. 16, 2024. The entire disclosure of the application referenced above is incorporated herein by reference.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells, and more particularly to cathode active materials for cathode electrodes.

Electric vehicles (EVs) such as battery electric vehicles (BEVs), hybrid vehicles, and/or fuel cell vehicles include one or more electric machines and a battery system including one or more battery cells, modules, and/or packs. A power control system is used to control charging and/or discharging of the battery system during charging and/or driving.

Battery cells include cathode electrodes, anode electrodes, and separators. The cathode electrodes include a cathode active material layer (including cathode active material) arranged on a cathode current collector. The anode electrodes include an anode active material layer (including anode active material) arranged on an anode current collector.

### SUMMARY

A cathode electrode includes a cathode current collector and a cathode active material layer arranged on at least one side of the cathode current collector. The cathode active material layer includes cathode active material comprising a plurality of cores each including a single crystal particle and a high entropy layer encapsulating each of the single crystal particles of the plurality of cores. The high entropy layer includes at least 5 different transition metal elements.

In other features, the plurality of cores comprises LiMnₓFe_{y}M_{1-x-y}PO₄ where x and y are in a range from 0 to 1. The plurality of cores is made of a material selected from a group consisting of lithium manganese iron phosphate (LMFP) and lithium iron phosphate (LFP). The plurality of cores includes manganese (Mn) having a molar ratio in a range from 0 to 0.8. The plurality of cores includes at least one transition metal selected from a group consisting of iron (Fe), nickel (Ni), cobalt (Co), aluminum (Al), magnesium (Mg), titanium (Ti), niobium (Nb), molybdenum (Mo), tungsten (W), and/or zirconium (Zr). The plurality of cores is made of a material selected from a group consisting of nickel cobalt manganese (NCM), nickel cobalt aluminum (NCA), nickel cobalt manganese aluminum (NCMA), cobalt-free nickel-manganese battery cells (NMₓ), and combinations thereof.

In other features, the plurality of cores includes Ni with a molar ratio greater than or equal to 0.5 and less than or equal to 0.95. The plurality of cores includes at least one transition metal (TM) selected from a group consisting of manganese (Mn), nickel (Ni), aluminum (Al), magnesium (Mg), and titanium (Ti).

In other features, an oxide layer encapsulates the high entropy layer of each of the plurality of cores.

A battery cell includes C of the cathode electrode, A anode electrodes, and S separators. C, A, and S are integers greater than one.

A cathode electrode includes a cathode current collector and a cathode active material layer arranged on at least one side of the cathode current collector. The cathode active material layer includes cathode active material comprising a plurality of cores each including a single crystal particle and a plurality of high entropy portions discontinuously located on each of the single crystal particles of the plurality of cores. The plurality of high entropy portions include at least 5 different transition metal elements.

In other features, the plurality of cores comprises LiMnₓFe_{y}M_{1-x-y}PO₄ where x and y are in a range from 0 to 1. The plurality of cores is made of a material selected from a group consisting of lithium manganese iron phosphate (LMFP) and lithium iron phosphate (LFP). The plurality of cores includes manganese (Mn) having a molar ratio in a range from 0 to 0.8. The plurality of cores includes at least one transition metal selected from a group consisting of iron (Fe), nickel (Ni), cobalt (Co), aluminum (Al), magnesium (Mg), titanium (Ti), niobium (Nb), molybdenum (Mo), tungsten (W), and/or zirconium (Zr). The plurality of cores is made of a material selected from a group consisting of nickel cobalt manganese (NCM), nickel cobalt aluminum (NCA), nickel cobalt manganese aluminum (NCMA), cobalt-free nickel-manganese battery cells (NMₓ), and combinations thereof.

In other features, the plurality of cores includes Ni with a molar ratio greater than or equal to 0.5 and less than or equal to 0.95. The plurality of cores includes at least one transition metal (TM) selected from a group consisting of manganese (Mn), nickel (Ni), aluminum (Al), magnesium (Mg), and titanium (Ti).

In other features, a plurality of oxide portions are discontinuously arranged on the plurality of cores.

A battery cell includes C of the cathode electrode, A anode electrodes, and S separators. C, A, and S are integers greater than one.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross sectional view of an example of a battery cell including anode electrodes, cathode electrodes, and separators according to the present disclosure;

FIG. 2 is a side cross sectional view of a cathode electrode with cathode active material according to the present disclosure;

FIG. 3 is a side cross sectional view of a cathode active material including a high entropy layer according to the present disclosure;

FIG. 4 is a side cross sectional view of a cathode active material including a high entropy layer and an oxide layer according to the present disclosure;

FIG. 5 is a side cross sectional view of a cathode active material including discontinuous high entropy layer according to the present disclosure;

FIG. 6 is a side cross sectional view of a cathode active material including discontinuous high entropy portions and discontinuous oxide portions according to the present disclosure;

FIG. 7 is a graph illustrating heat flow as a function of temperature for single crystal NCMA and single crystal NCMA with a high entropy layer according to the present disclosure;

FIGS. 8 and 9 are graphs illustrating initial coulombic efficiency for single crystal NCM and single crystal NCM with a high entropy layer according to the present disclosure; and

FIG. 10 is a graph illustrating cycling performance for single crystal NCM and single crystal NCM with a high entropy layer according to the present disclosure.

In the drawings, reference numbers may be reused to identify similar and/or identical elements.

### DETAILED DESCRIPTION

While battery cells according to the present disclosure are shown in the context of electric vehicles, the battery cells can be used in stationary applications and/or other applications.

A cathode electrode includes a cathode active material layer arranged on one or both sides of a cathode current collector. The cathode active material layer includes a cathode active material, an optional conductive filler, an optional binder, and/or other materials.

Cathode active material including high nickel content (e.g., nickel cobalt manganese aluminum (NCMA)), is widely used in battery cells. However, this cathode active material is prone to thermal instability. Lithium manganese iron phosphate (LMFP) and lithium iron phosphate (LFP) are another widely applied low cost cathode active material.

An outer surface of some cathode active materials can be unstable. The unstable surface may lead to problems including manganese/iron (Mn/Fe) dissolution in LMFP and LFP-based battery cells or O₂ evolution in NCM/NCMA-based battery cells. When these problems occur, cycling life of the battery cell is reduced and/or safety issues may occur.

Attempts have been made to manufacture single crystal, high entropy (HE) cathode active material. However, due to kinetic limitations, it is difficult to directly synthesize single crystal HE cathode active material.

The present disclosure relates to cathode active material including a core comprising single crystal cathode (SCC) active material including LMFP/LFP or NCM/NCA/NCMA/NMₓ material. In some examples, an outer layer or portions are formed on the core 110 including a high-entropy (HE) material. The outer layer provides a more stable surface structure and can dramatically improve the cycling life and the thermal stability of the battery cells.

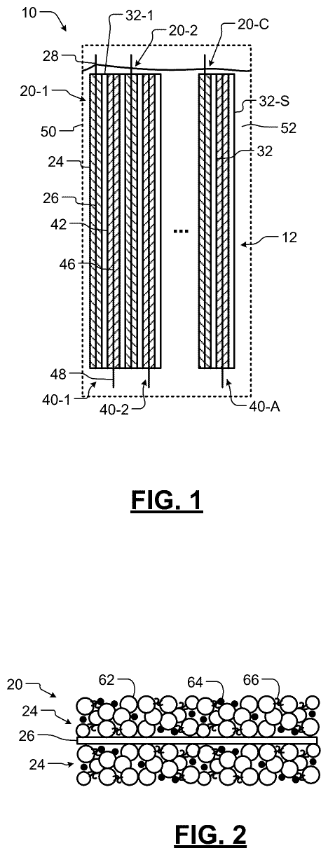

Referring now to FIG. 1, a battery cell 10 includes C cathode electrodes 20, A anode electrodes 40, and S separators 32 arranged in a predetermined sequence in a battery cell stack 12, where C, S and A are integers greater than zero. The battery cell stack 12 is arranged in an enclosure 50. Liquid electrolyte 52 is added to the enclosure 50.

The C cathode electrodes 20-1, 20-2, . . . , and 20-C include a cathode active material layer 24 arranged on one or both sides of a cathode current collector 26. The A anode electrodes 40-1, 40-2, . . . , and 40-A include anode active material layers 42 arranged on one or both sides of the anode current collectors 46. The S separators 32-1, 32-2, . . . , and 32-S are arranged between the C cathode electrodes 20 and the A anode electrodes 40.

During charging/discharging, the A anode electrodes 40 and the C cathode electrodes 20 exchange lithium ions. In some examples, the cathode active material layers 24 and/or the anode active material layers 42 comprise coatings including one or more active materials, one or more conductive additives, and/or one or more binder materials that are cast or applied onto one or both sides of the current collectors 26 and/or 46, respectively.

In some examples, the cathode current collector 26 and/or the anode current collector 46 comprise metal foil, metal mesh, perforated metal, 3 dimensional (3D) metal foam, and/or expanded metal. In some examples, the current collectors are made of one or more materials selected from a group consisting of copper, stainless steel, brass, bronze, zinc, aluminum, and/or alloys thereof. External tabs 28 and 48 are connected to the current collectors of the cathode electrodes and anode electrodes, respectively, and can be arranged on the same or different sides of the battery cell stack 12. The external tabs 28 and 48 are connected to terminals of the battery cells.

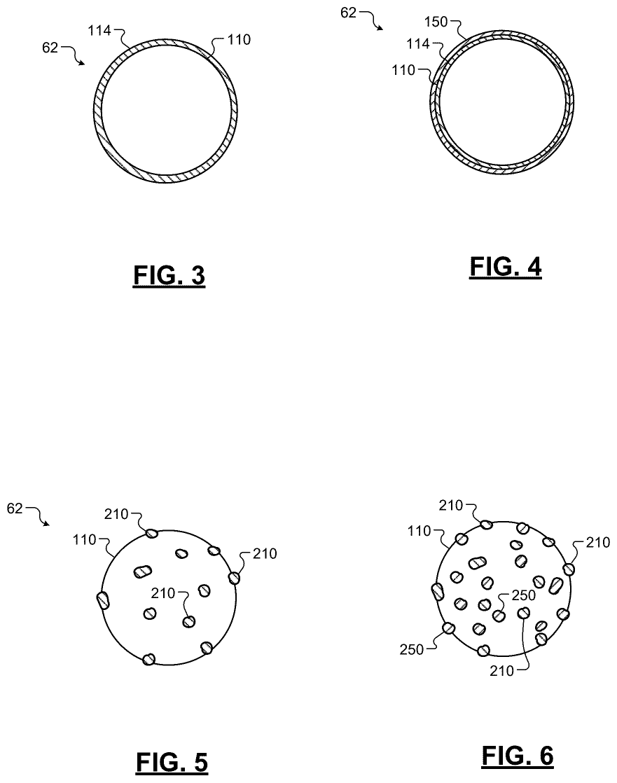

Referring now to FIGS. 2 and 3, one of the C cathode electrodes 20 is shown in more detail. The cathode active material layer 24 includes a cathode active material 62, an optional conductive additive 64, and an optional binder 66. In FIG. 3, an example of the cathode active material 62 is shown to include a core 110. A high entropy (HE) layer 114 or shell encapsulates an outer surface of the core 110. In some examples, the HE layer 114 is a continuous layer.

In some examples, the core of the cathode active material 62 comprises an overall layered cathode material structure with space group R-3m. In some examples, the core 110 comprises single crystal particles without obvious cracks/voids inside the particles.

In some examples, the core 110 is made of a material selected from a group consisting of nickel cobalt manganese (NCM), nickel cobalt aluminum (NCA), nickel cobalt manganese aluminum (NCMA), cobalt-free nickel-manganese battery cells (NMₓ), and combinations thereof. In some examples, in a fraction of the all transition metals, Ni is in a ratio of greater than or equal to 0.5 and less than or equal to 0.95. In some examples, the core 110 further comprises one or more other transition metals (TMs) selected from a group consisting of manganese (Mn), nickel (Ni), aluminum (Al), magnesium (Mg), and titanium (Ti). In some examples, the core 110 comprises LiNi_{0.88}Mn_{0.1}Al_{0.005}Mg_{0.005}O₂. In some examples, the HE layer 114 comprises lithium. In some examples, the HE layer 114 comprises at least 5 TM elements. In some examples, the HE layer 114 comprises LiNi_{0.8}Mn_{0.13}Ti_{0.02}Mg_{0.02}Nb_{0.01}Mo_{0.02}Zr_{0.05}O₂.

In other examples, the core 110 is electrochemically active and has a formula LiMnₓFe_{y}M_{1-x-y}PO₄ where x and y are in a range from 0 to 1. In some examples, the core 110 comprises lithium manganese iron phosphate (LMFP), lithium iron phosphate (LFP). In some examples, in a fraction of all of the TM in the core, Mn has a ratio in a range from 0 to 0.8, and M has a ratio equal or less than 0.05. In some examples, the core 110 includes one or more other TMs selected from a group consisting of iron (Fe), nickel (Ni), cobalt (Co), aluminum (Al), magnesium (Mg), titanium (Ti), niobium (Nb), molybdenum (Mo), tungsten (W), and/or zirconium (Zr). In some examples, the HE layer 114 includes lithium. In some examples, the HE layer 114 comprises at least 5 TM elements. In some examples, the HE layer 114 comprises LiMn_{0.6}Fe_{0.3}Ti_{0.02}Mg_{0.02}Nb_{0.02}Mo_{0.02}Zr_{0.02}O₂.

Referring now to FIG. 4, the cathode active material 62 includes the core 110, the HE layer 114, and an oxide coating 150 encapsulating an outer surface of the HE layer 114. In some examples, the HE layer 114 and the oxide coating 150 are continuous layers. In some examples, the oxide layer are selected from a group consisting of aluminum oxide or alumina (Al₂O₃), zirconium dioxide (ZrO₂), and/or other suitable oxide coatings.

Referring now to FIGS. 5 and 6, the cathode active material 62 can include the HE material (or HE material and the oxide material) as discontinuous coatings. In FIG. 5, the cathode active material 62 includes the core 110 and a plurality of HE portions 210 or islands that are arranged in a discontinuous manner on an outer surface of the core 110. In FIG. 6, the cathode active material 62 includes the core 110, the plurality of HE portions 210 or islands, and a plurality of oxide portions 250 or islands that are arranged in a discontinuous manner on an outer surface of the core 110.

In some examples, the core 110 is made of the materials set forth above. In some examples, the HE portions 210 are made of the materials set forth above. In some examples, the oxide portions are selected from a group consisting of aluminum oxide or alumina (Al₂O₃), zirconium dioxide (ZrO₂), and/or other suitable oxide coatings.

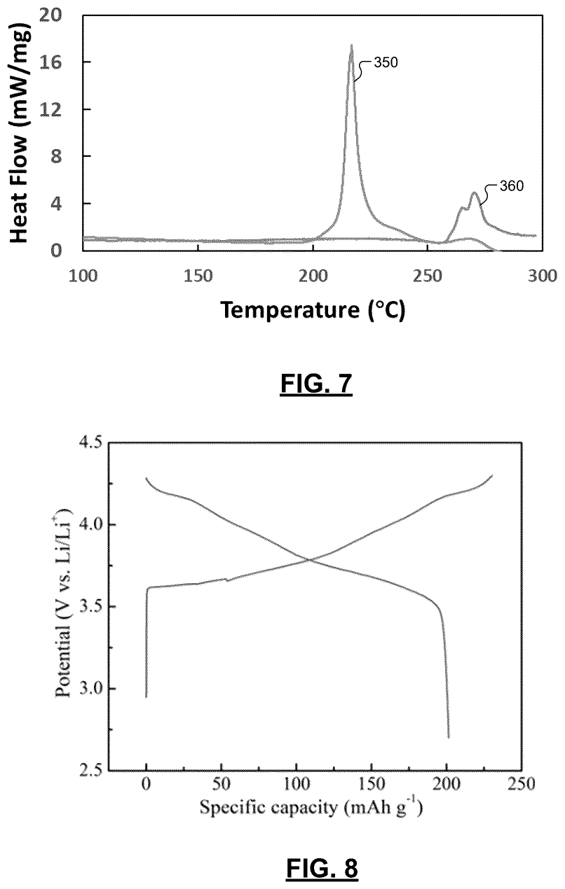

Referring now to FIG. 7, the cathode active material described herein has improved thermal stability. A single crystal core of NCMA 350 and a single crystal core of NCMA with a HE layer 360 are shown. Thermal stability of the cathode active material was increased from 217° C. to 270° C., which improves safety. The intensity of heat flow was also reduced for the cathode active material including the HE layer.

Referring now to FIGS. 8 to 10, initial coulombic efficiency is shown for a single crystal core of NCM (FIG. 8) and a single crystal core of NCM with a HE layer (FIG. 9). Initial coulombic efficiency increased from 87% to 93%.

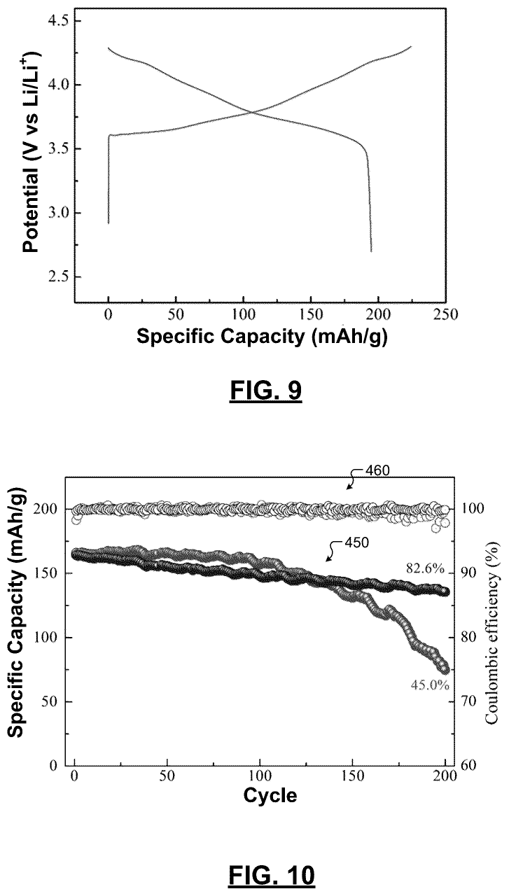

In FIG. 10, cycling performance of the single crystal core of NCM at 450 and the single crystal core of NCM with the HE layer at 460 is shown. The cycling efficiency of the single crystal core of NCM with the HE layer 460 is significantly improved relative to the single crystal core of NCM.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A cathode electrode, comprising:
a cathode current collector; and
a cathode active material layer arranged on at least one side of the cathode current collector,
wherein the cathode active material layer includes cathode active material comprising:
a plurality of cores each including a single crystal particle; and
a high entropy layer encapsulating each of the single crystal particles of the plurality of cores, wherein the high entropy layer includes at least 5 different transition metal elements.

2. The cathode electrode of claim 1, wherein the plurality of cores comprises LiMnₓFe_{y}M_{1-x-y}PO₄ where x and y are in a range from 0 to 1.

3. The cathode electrode of claim 1, wherein the plurality of cores is made of a material selected from a group consisting of lithium manganese iron phosphate (LMFP) and lithium iron phosphate (LFP).

4. The cathode electrode of claim 1, wherein the plurality of cores includes manganese (Mn) having a molar ratio in a range from 0 to 0.8.

5. The cathode electrode of claim 4, where the plurality of cores includes at least one transition metal selected from a group consisting of iron (Fe), nickel (Ni), cobalt (Co), aluminum (Al), magnesium (Mg), titanium (Ti), niobium (Nb), molybdenum (Mo), tungsten (W), and/or zirconium (Zr).

6. The cathode electrode of claim 1, wherein the plurality of cores is made of a material selected from a group consisting of nickel cobalt manganese (NCM), nickel cobalt aluminum (NCA), nickel cobalt manganese aluminum (NCMA), cobalt-free nickel-manganese battery cells (NM_{X}), and combinations thereof.

7. The cathode electrode of claim 1, wherein the plurality of cores includes Ni with a molar ratio greater than or equal to 0.5 and less than or equal to 0.95.

8. The cathode electrode of claim 7, wherein the plurality of cores includes at least one transition metal (TM) selected from a group consisting of manganese (Mn), nickel (Ni), aluminum (Al), magnesium (Mg), and titanium (Ti).

9. The cathode electrode of claim 1, further comprising an oxide layer encapsulating the high entropy layer of each of the plurality of cores.

10. A battery cell comprising:
C of the cathode electrode of claim 1;
A anode electrodes; and
S separators, wherein C, A, and S are integers greater than one.

11. A cathode electrode, comprising:
a cathode current collector; and
a cathode active material layer arranged on at least one side of the cathode current collector,
wherein the cathode active material layer includes cathode active material comprising:
a plurality of cores each including a single crystal particle; and
a plurality of high entropy portions discontinuously located on each of the single crystal particles of the plurality of cores,
wherein the plurality of high entropy portions include at least 5 different transition metal elements.

12. The cathode electrode of claim 11, wherein the plurality of cores comprises LiMnₓFe_{y}M_{1-x-y}PO₄ where x and y are in a range from 0 to 1.

13. The cathode electrode of claim 11, wherein the plurality of cores is made of a material selected from a group consisting of lithium manganese iron phosphate (LMFP) and lithium iron phosphate (LFP).

14. The cathode electrode of claim 11, wherein the plurality of cores includes manganese (Mn) having a molar ratio in a range from 0 to 0.8.

15. The cathode electrode of claim 14, where the plurality of cores includes at least one transition metal selected from a group consisting of iron (Fe), nickel (Ni), cobalt (Co), aluminum (Al), magnesium (Mg), titanium (Ti), niobium (Nb), molybdenum (Mo), tungsten (W), and/or zirconium (Zr).

16. The cathode electrode of claim 11, wherein the plurality of cores is made of a material selected from a group consisting of nickel cobalt manganese (NCM), nickel cobalt aluminum (NCA), nickel cobalt manganese aluminum (NCMA), cobalt-free nickel-manganese battery cells (NMₓ), and combinations thereof.

17. The cathode electrode of claim 11, wherein the plurality of cores includes Ni with a molar ratio greater than or equal to 0.5 and less than or equal to 0.95.

18. The cathode electrode of claim 17, wherein the plurality of cores includes at least one transition metal (TM) selected from a group consisting of manganese (Mn), nickel (Ni), aluminum (Al), magnesium (Mg), and titanium (Ti).

19. The cathode electrode of claim 11, further comprising a plurality of oxide portions discontinuously arranged on the plurality of cores.

20. A battery cell comprising:
C of the cathode electrode of claim 11;
A anode electrodes; and
S separators, wherein C, A, and S are integers greater than one.
